(19) United States
(12) Patent Application Publication
(10) Pub. No.: US 2023/0161087 A1
(43) Pub. Date: May 25, 2023

(54) OPTICAL FILM, METHOD FOR MANUFACTURING THE SAME, AND BACKLIGHT MODULE

(71) Applicant: NAN YA PLASTICS CORPORATION, Taipei (TW)

(72) Inventors: Te-Chao LIAO, Taipei (TW); Chun-Che TSAO, Taipei (TW); Ren-Yu Liao, New Taipei City (TW)

(21) Appl. No.: 17/973,512

(22) Filed: Oct. 25, 2022

(30) Foreign Application Priority Data
Nov. 23, 2021 (TW) 110143487

(51) Int. Cl. G02B 5/20; F21V 8/00; G02B 1/04; H01L 51/00

(52) U.S. Cl. CPC G02B 5/206; G02B 6/0023; G02B 1/04; H01L 51/0036; H01L 51/0035; G02B 2207/109; G02B 2207/101; B82Y 20/00

(57) ABSTRACT

An optical film, a method for manufacturing the same, and a backlight module are provided. The optical film is formed by a cadmium-free quantum dot gel layer, which includes a first polymer and a plurality of cadmium-free quantum dots dispersed therein. The first polymer includes: 1 wt % to 5 wt % of a photoinitiator; 3 wt % to 30 wt % of scattering particles; 10 wt % to 40 wt % of a thiol compound; 5 wt % to 30 wt % of a monofunctional acrylic monomer; 5 wt % to 20 wt % of a bifunctional acrylic monomer; 10 wt % to 40 wt % of a multifunctional acrylic monomer; 5 wt % to 20 wt % of an organosilicon grafted oligomer; and 100 ppm to 2,000 ppm of an inhibitor. The thiol compound includes a primary mercaptan and a secondary mercaptan, and a weight ratio of the primary mercaptan to the secondary mercaptan ranges from 1:3 to 3:1.

### CROSS-REFERENCE TO RELATED PATENT APPLICATION

This application claims the benefit of priority to Taiwan Patent Application No. 110143487, filed on Nov. 23, 2021. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a backlight module, a cadmium-free optical film, and a method for manufacturing the cadmium-free optical film, and more particularly to a backlight module, and a cadmium-free quantum dot optical film and a method for manufacturing the same capable of being applied to the backlight module and an LED package.

### BACKGROUND OF THE DISCLOSURE

In recent years, with the progression of display technologies, people have higher expectations for the quality of display devices. Quantum dot technology has attracted recent attention from researchers due to their unique quantum confinement effects. Compared with conventional organic light-emitting materials, the luminous efficacy of the quantum dots has advantages of having a narrow full width at half maximum, small particles, no scattering loss, a spectrum that is scalable with size, and stable photochemical performance. In addition, optical, electrical, and transmission properties of the quantum dots can be adjusted through a synthesis process. These advantages have contributed to the importance of the quantum dots. Recently, polymer composite materials that contain the quantum dots have been used in fields such as those relating to backlights and display devices.

The representative quantum dots are cadmium-based quantum dots that include cadmium selenide (CdSe), cadmium telluride (CdTe), and cadmium sulfide (CdS). An advantage of the cadmium-based quantum dots is having a wider energy band. However, heavy metals of cadmium have high toxicity and a high environmental load, and can cause the risks of heavy metal pollution in the environment (not only at a production end but also during disposal of the display devices or waste treatment). Further, service life of the quantum dots may also be affected by acid hydrolysis occurred during a conventional manufacturing process.

The quantum dots that do not include cadmium (i.e., cadmium-free quantum dots) can be, for example, chalcopyrite quantum dots that include copper indium sulfide (CuInS₂) or silver indium sulfide (AgInS₂), indium phosphide (InP) quantum dots, or perovskite quantum dots, which have disadvantages of being not resistant to moisture and oxygen. Further, a quantum dot film that is prepared by use of such quantum dots needs to be additionally attached with a water-oxygen barrier film layer, so as to improve barrier properties of an optical film against moisture and oxygen and prolong the lifespan of the quantum dots.

Therefore, how to enhance water-oxygen barrier effects of a cadmium-free quantum dot film through an improvement in preparation of a quantum dot film layer, so as to omit the water-oxygen barrier film layer and overcome the above-mentioned deficiencies, has become one of the important issues to be solved in the industry.

### SUMMARY OF THE DISCLOSURE

In response to the above-referenced technical inadequacies, the present disclosure provides a backlight module, and a cadmium-free quantum dot optical film and a method for manufacturing the same capable of being applied to the backlight module and an LED package.

In one aspect, the present disclosure provides an optical film. The optical film is formed by a cadmium-free quantum dot gel layer, and the cadmium-free quantum dot gel layer includes a first polymer and a plurality of cadmium-free quantum dots dispersed in the first polymer. To be specific, based on a total weight of the cadmium-free quantum dot gel layer being 100 wt %, a content of the cadmium-free quantum dots ranges from 0.1 wt % to 5 wt %. The first polymer includes: 1 wt % to 5 wt % of a photoinitiator; 3 wt % to 30 wt % of scattering particles; 10 wt % to 40 wt % of a thiol compound; 5 wt % to 30 wt % of a monofunctional acrylic monomer; 5 wt % to 20 wt % of a bifunctional acrylic monomer; 10 wt % to 40 wt % of a multifunctional acrylic monomer; 5 wt % to 20 wt % of an organosilicon grafted oligomer; and 100 ppm to 2,000 ppm of an inhibitor. More specifically, the thiol compound includes a primary mercaptan and a secondary mercaptan, and a weight ratio of the primary mercaptan to the secondary mercaptan ranges from 1:3 to 3:1.

In certain embodiments, the primary mercaptan is selected from the group consisting of: 2, 2′-(ethylenedioxy)diethyl mercaptan, 2, 2′-thiodiethyl mercaptan, trimethylolpropane tris(3-mercaptopropionate), polyethylene glycol dithiol, pentaerythritol tetrakis(3-mercaptopropionate), and ethylene glycol dimercaptoacetate. The secondary mercaptan is selected from the group consisting of: ethyl 2-mercaptopropionate, pentaerythritol tetrakis(3-mercaptobutyrate), 1, 3, 5-tris(3-mercapto butyloxyethyl)-1, 3, 5-triazine-2, 4, 6(1H, 3H, 5H)-trione, and 1,4-butanediol bis(3-mercaptobutyric acid) ester.

In certain embodiments, the monofunctional acrylic monomer is selected from the group consisting of: dicyclopentadiene methacrylate, triethylene glycol ethyl ether methacrylate, alkoxylated lauryl acrylate, isobornyl methacrylate, lauryl methacrylate, stearyl methacrylate, lauryl acrylate, isobornyl acrylate, tridecyl acrylate, caprolactone acrylate, octylphenol acrylate, and alkoxylated acrylate.

In certain embodiments, the bifunctional acrylic monomer is selected from the group consisting of: bisphenol A ethoxylate dimethacrylate, 1,3-butanediol diacrylate, 1,4-butanediol dimethacrylate, 1,6-hexanediol diacrylate, tetra(ethylene glycol) diacrylate, and polyethylene glycol diacrylate.

In certain embodiments, the multifunctional acrylic monomer is selected from the group consisting of: trimethylolpropane triacrylate, ethoxylated trimethylolpropane triacrylate, ditrimethylolpropane tetraacrylate, pentaerythritol tetraacrylate, dipentaerythritol pentaacrylate, and ethoxylated pentaerythritol tetraacrylate.

In certain embodiments, the organosilicon grafted oligomer is a polyoctahedral silsesquioxane.

In certain embodiments, the cadmium-free quantum dots are quantum dots that have a core-shell structure. A core of the core-shell structure is at least one selected from the group consisting of: silicon (Si), germanium (Ge), selenium (Se), zinc (Zn), tellurium (Te), boron (B), nitrogen (N), phosphorus (P), arsenic (As), zinc sulfide (ZnS), zinc selenide (ZnSe), zinc telluride (ZnTe), mercury sulfide (HgS), mercury selenide (HgSe), mercury telluride (HgTe), aluminum nitride (AlN), aluminum phosphide (AlP), aluminum arsenide (AlAs), aluminum antimonide (AlSb), gallium nitride (GaN), gallium phosphide (GaP), gallium arsenide (GaAs), gallium antimonide (GaSb), gallium selenide (GaSe), indium nitride (InN), indium phosphide (InP), indium arsenide (InAs), indium antimonide (InSb), thallium nitride (TlN), thallium phosphide (TlP), thallium arsenide (TlAs), thallium antimonide (TlSb), lead sulfide (PbS), lead selenide (PbSe), and lead telluride (PbTe).

In certain embodiments, a shell of the core-shell structure is at least one selected from the group consisting of: zinc oxide (ZnO), zinc sulfide (ZnS), zinc selenide (ZnSe), zinc telluride (ZnTe), magnesium oxide (MgO), magnesium sulfide (MgS), magnesium selenide (MgSe), magnesium telluride (MgTe), mercury oxide (HgO), mercury sulfide (HgS), mercury selenide (HgSe), mercury telluride (HgTe), aluminum nitride (AlN), aluminum phosphide (AlP), aluminum arsenide (AlAs), aluminum antimonide (AlSb), gallium nitride (GaN), gallium phosphide (GaP), gallium arsenide (GaAs), gallium antimonide (GaSb), indium nitride (InN), indium phosphide (InP), indium arsenide (InAs), indium antimonide (InSb), thallium nitride (TlN), thallium phosphide (TlP), thallium arsenide (TlAs), thallium antimonide (TlSb), lead sulfide (PbS), lead selenide (PbSe), lead telluride (PbTe), indium gallium phosphide (InₓGa₁₋ₓP), copper indium sulfide (CuInS₂), copper indium selenide (CuInSe₂), copper indium sulfide selenide (CuInSₓSe₂₋ₓ), copper indium gallium sulfide (CuInₓGa₁₋ₓS₂), copper indium gallium selenide (CuInₓGa₁₋ₓSe₂), copper gallium sulfide (CuGaS₂), copper indium aluminum selenide (CuInₓAl₁₋ₓSe₂), copper gallium aluminum selenide (CuGaₓAl₁₋ₓSe₂), copper indium sulfide zinc sulfide (CuInS₂ₓZnS₁₋ₓ), and copper indium selenide zinc selenide (CuInSe₂ₓZnSe₁₋ₓ).

In another aspect, the present disclosure provides a method for manufacturing an optical film, which includes: (a) dispersing a plurality of cadmium-free quantum dots in a first polymer to obtain a cadmium-free quantum dot composite material; (b) placing the cadmium-free quantum dot composite material onto a release substrate, and curing the cadmium-free quantum dot composite material; and (c) removing the release substrate, so as to obtain the optical film. To be specific, based on a total weight of the cadmium-free quantum dot composite material being 100 wt %, a content of the cadmium-free quantum dots ranges from 0.1 wt % to 5 wt %. The first polymer includes: 1 wt % to 5 wt % of a photoinitiator; 3 wt % to 30 wt % of scattering particles; 10 wt % to 40 wt % of a thiol compound; 5 wt % to 30 wt % of a monofunctional acrylic monomer; 5 wt % to 20 wt % of a bifunctional acrylic monomer; 10 wt % to 40 wt % of a multifunctional acrylic monomer; 5 wt % to 20 wt % of an organosilicon grafted oligomer; and 100 ppm to 2,000 ppm of an inhibitor. More specifically, the thiol compound includes a primary mercaptan and a secondary mercaptan, and a weight ratio of the primary mercaptan to the secondary mercaptan ranges from 1:3 to 3:1.

In yet another aspect, the present disclosure provides a backlight module, which includes a light guide unit, at least one light emitting unit, and an optical film. The light guide unit has a light input side, and the at least one light emitting unit corresponds in position to the light input side. The optical film corresponds in position to the light input side, and is disposed between the light guide unit and the at least one light emitting unit. The optical film is formed by a cadmium-free quantum dot gel layer, and the cadmium-free quantum dot gel layer includes a first polymer and a plurality of cadmium-free quantum dots dispersed in the first polymer. Based on a total weight of the cadmium-free quantum dot gel layer being 100 wt %, a content of the cadmium-free quantum dots ranges from 0.1 wt % to 5 wt %. The first polymer includes: 1 wt % to 5 wt % of a photoinitiator; 3 wt % to 30 wt % of scattering particles; 10 wt % to 40 wt % of a thiol compound; 5 wt % to 30 wt % of a monofunctional acrylic monomer; 5 wt % to 20 wt % of a bifunctional acrylic monomer; 10 wt % to 40 wt % of a multifunctional acrylic monomer; 5 wt % to 20 wt % of an organosilicon grafted oligomer; and 100 ppm to 2,000 ppm of an inhibitor. More specifically, the thiol compound includes a primary mercaptan and a secondary mercaptan, and a weight ratio of the primary mercaptan to the secondary mercaptan ranges from 1:3 to 3:1.

Therefore, in the optical film, the method for manufacturing the same, and the backlight module provided by the present disclosure, by virtue of the thiol compound including the primary mercaptan and the secondary mercaptan and the weight ratio of the primary mercaptan to the secondary mercaptan ranging from 1:3 to 3:1, water-oxygen resistant properties of the cadmium-free quantum dot gel layer can be enhanced. In addition, a shielding layer does not need to be attached to one side or both sides of the cadmium-free quantum dot gel layer, such that a film layer thickness can be effectively reduced. Accordingly, this optical film can be applied to optical products that are light and thin in size.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic cross-sectional view of an optical film according to one embodiment of the present disclosure;

FIG. 2 is a flowchart illustrating a method for manufacturing the optical film according to one embodiment of the present disclosure; and

FIG. 3 is a schematic cross-sectional view of a backlight module according to one embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

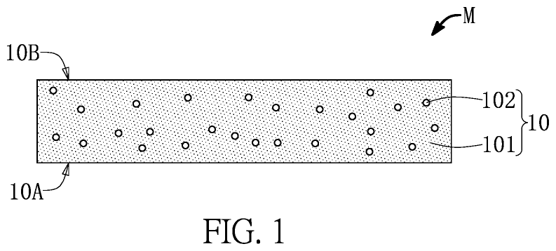

Referring to FIG. 1, a first embodiment of the present disclosure provides an optical film M, which is formed by a cadmium-free quantum dot gel layer 10. In detail, the cadmium-free quantum dot gel layer 10 includes a first polymer 101 and a plurality of cadmium-free quantum dots 102 dispersed in the first polymer 101. Moreover, the cadmium-free quantum dot gel layer 10 has a first surface 10A and a second surface 10B. Both of the first surface 10A and the second surface 10B are exposed and not covered. A thickness of the optical film M is a thickness of the cadmium-free quantum dot gel layer 10, which ranges approximately from 20 μm to 120 μm.

A more detailed description is provided for a composition ratio of a cadmium-free quantum dot gel layer. The cadmium-free quantum dot gel layer includes a first polymer and a plurality of cadmium-free quantum dots dispersed in the first polymer. To be specific, based on a total weight of the cadmium-free quantum dot gel layer being 100 wt %, a content of the cadmium-free quantum dots ranges from 0.1 wt % to 5 wt %. In addition, the first polymer includes: 1 wt % to 5 wt % of a photoinitiator; 3 wt % to 30 wt % of scattering particles; 10 wt % to 40 wt % of a thiol compound; 5 wt % to 30 wt % of a monofunctional acrylic monomer; 5 wt % to 20 wt % of a bifunctional acrylic monomer; 10 wt % to 40 wt % of a multifunctional acrylic monomer; 5 wt % to 20 wt % of an organosilicon grafted oligomer; and 100 ppm to 2,000 ppm of an inhibitor.

The photoinitiator can be selected from the group consisting of: 1-hydroxycyclohexyl phenyl ketone, benzoyl isopropanol, tribromomethyl phenyl sulfone, and diphenyl(2, 4, 6-trimethylbenzoyl)phosphine oxide. However, curing cannot be easily achieved if a content of the photoinitiator is less than 1 wt %, and volatility of the overall properties of a gel material will be affected if the content of the photoinitiator is more than 5 wt %.

The scattering particles have a particle size ranging from 0.5 μm to 20 μm, and are surface-treated microbeads. The material of the microbeads can be acrylic, silicon dioxide, germanium dioxide, titanium dioxide, zirconium dioxide, aluminum oxide or polystyrene. Preferably, the scattering particles are acrylic, silicon dioxide or polystyrene microbeads that are surface-treated, and the particle size thereof ranges from 0.5 μm to 10 μm. A refractive index of the scattering particles ranges approximately from 1.39 to 1.45. Due to the scattering particles, light scattering of the quantum dots is improved, so that light generated through the cadmium-free quantum dot gel layer is more uniform. If a content of the scattering particles is less than 3 wt %, the haze is insufficient. If the content of the scattering particles is more than 30 wt %, the haze will be too much, which can result in insufficiency of a resin content in the overall material, affect dispersity, and increase processing difficulty. In some embodiments, the content of the scattering particles can also be 5 wt %, 10 wt %, 15 wt %, 20 wt %, 25 wt %, or 30 wt %. In the present disclosure, the particle size of the scattering particles is measured by an Anton Paar Litesizer 500.

Specifically, the thiol compound includes a primary mercaptan and a secondary mercaptan. Through mixing the primary mercaptan and the secondary mercaptan, a reaction rate of the acrylic monomer can be adjusted, so as to produce a cadmium-free quantum dot gel layer that has good weather resistance. The acrylic monomer may react too violently when only the primary mercaptan is added, but the reaction effect of the acrylic monomer is poor when only the secondary mercaptan is added, both of which fail to achieve the desired weather resistance of the present disclosure. Hence, in the present disclosure, the primary mercaptan and the secondary mercaptan need to be used at the same time. A weight ratio of the primary mercaptan to the secondary mercaptan ranges from 1:3 to 3:1. Preferably, an added amount of the primary mercaptan is greater than an added amount of the secondary mercaptan. The primary mercaptan is selected from the group consisting of: 2, 2′-(ethylenedioxy)diethyl mercaptan, 2, 2′-thiodiethyl mercaptan, trimethylolpropane tris(3-mercaptopropionate), polyethylene glycol dithiol, pentaerythritol tetrakis(3-mercaptopropionate), and ethylene glycol dimercaptoacetate. The secondary mercaptan is selected from the group consisting of: ethyl 2-mercaptopropionate, pentaerythritol tetrakis(3-mercaptobutyrate), 1, 3, 5-tris(3-mercapto butyloxyethyl)-1, 3, 5-triazine-2, 4, 6(1H, 3H, 5H)-trione, and 1,4-butanediol bis(3-mercaptobutyric acid) ester.

The thiol compound is a non-aromatic compound that contains a sulfhydryl (—SH) functional group, which provides a functional group that can form a better bond with the quantum dots. Accordingly, the dispersity of the quantum dots can be improved. A content of the thiol compound is higher in comparison to that of the related art, which results in a higher degree of polymerization. If the content of the thiol compound is less than 10 wt %, no effect can be achieved. However, if said content is more than 40 wt %, the gel material becomes too soft and is easily bent. Further, there is an issue of poor adhesion, which can negatively affect water-oxygen barrier effects of an optical film In some embodiments, the content of the thiol compound can also be 10 wt %, 15 wt %, 20 wt %, 25 wt %, 30 wt %, 35 wt %, or 40 wt %.

Furthermore, the monofunctional acrylic monomer is selected from the group consisting of: dicyclopentadiene methacrylate, triethylene glycol ethyl ether methacrylate, alkoxylated lauryl acrylate, isobornyl methacrylate, lauryl methacrylate, stearyl methacrylate, lauryl acrylate, isobornyl acrylate, tridecyl acrylate, caprolactone acrylate, octylphenol acrylate, and alkoxylated acrylate. Too low a content of the monofunctional acrylic monomer can result in poor dispersity of the quantum dots. However, if the content of the monofunctional acrylic monomer is too high, a polymerization efficiency will decrease and the weather resistance will become poor. In some embodiments, the content of the monofunctional acrylic monomer can also be 5 wt %, 10 wt %, 15 wt %, 20 wt %, 25 wt %, or 30 wt %.

The bifunctional acrylic monomer is selected from the group consisting of: bisphenol A ethoxylate dimethacrylate, 1,3-butanediol diacrylate, 1,4-butanediol dimethacrylate, 1,6-hexanediol diacrylate, tetra(ethylene glycol) diacrylate, and polyethylene glycol (400) diacrylate. Specifically, the bifunctional acrylic monomer has good compatibility with surface ligands of the quantum dots, and its property is in-between a mono-functional group and a multi-functional group. In some embodiments, a content of the bifunctional acrylic monomer can also be 5 wt %, 10 wt %, 15 wt %, or 20 wt %.

The multifunctional acrylic monomer is selected from the group consisting of: trimethylolpropane triacrylate, ethoxylated (20) trimethylolpropane triacrylate, ditrimethylolpropane tetraacrylate, pentaerythritol tetraacrylate, dipentaerythritol pentaacrylate, and ethoxylated (4) pentaerythritol tetraacrylate. If the multifunctional acrylic monomer is added in an excessive amount, the gel material may easily become too brittle and be prone to breakage. Furthermore, the multifunctional acrylic monomer does not include the above-mentioned bifunctional acrylic monomer. In some embodiments, a content of the multifunctional acrylic monomer can also be 10 wt %, 15 wt %, 20 wt %, 25 wt %, 30 wt %, 35 wt %, or 40 wt %.

The organosilicon grafted oligomer is a polyoctahedral silsesquioxane. The organosilicon grafted oligomer can not only increase the weather resistance of a polymer, but can also enhance the mechanical strength of the polymer. Preferably, macromolecules of the polyoctahedral silsesquioxane in a web structure have a molecular weight (Mw) that is greater than 3,000, so that the cadmium-free quantum dot gel layer can be better protected. In detail, a weight-average molecular weight of the polyoctahedral silsesquioxane is between 3,000 g/mol and 10,000 g/mol. Preferably, the weight-average molecular weight of the polyoctahedral silsesquioxane can be 4,000 g/mol, 5,000 g/mol, 6,000 g/mol, 7,000 g/mol, 8,000 g/mol, or 9,000 g/mol. When a shielding layer is omitted from a conventional optical film, not only will said optical film have decreased water and oxygen tolerance, but its mechanical strength will also be insufficient. 5 wt % to 20 wt % of the organosilicon grafted oligomer can enhance the mechanical strength of the cadmium-free quantum dot gel layer. If a content of the organosilicon grafted oligomer exceeds the above-mentioned range, the dispersity and the processability of the cadmium-free quantum dot gel layer can be affected, and the costs can be increased. In some embodiments, the content of the organosilicon grafted oligomer can also be 5 wt %, 10 wt %, 15 wt %, or 20 wt %.

The inhibitor is selected from the group consisting of: pyrogallol (PYR), hydroquinone, catechol, potassium iodide-iodine mixtures, hindered phenol antioxidants, aluminum/ammonium cupferronate salt (N-nitrosophenyl hydroxylamine ammonium salt), N-nitroso-N-phenylhydroxylamine aluminum salt, 3-propenylphenol, triaryl phosphines, triaryl phosphites, phosphonic acid, and a combination of alkenyl-phenol and cupferronate salt.

The inhibitor can effectively slow down the reaction rate, and prevent component formulas from affecting one another. For example, the thiol compound and the multifunctional acrylic monomer are prone to self-react at a room temperature. An addition of the inhibitor during preparation allows for an improved processability and a more stable preservation. However, an inhibition effect cannot be achieved if an added amount of the inhibitor is less than 100 ppm, and a photocuring efficiency can be affected if the added amount is more than 2,000 ppm. It should be noted that, although the added amount of the inhibitor is not high, an effective amount of the inhibitor must be added in a macromolecule system where the thiol compound and the multifunctional acrylic monomer are both present.

The cadmium-free quantum dots are quantum dots that do not contain a cadmium element, and can be selected from quantum dots that have a homogeneous single structure or a core-shell structure, multi-shell quantum dots (i.e., having a plurality of shell layers), or gradient-structured quantum dots. More specifically, in the core-shell structure of the gradient-structured quantum dots, an element content of a core layer gradually decreases from the core to the shell, and an element content of a shell layer gradually increases from the core to the shell.

The cadmium-free quantum dots are preferably the quantum dots that have the core-shell structure. The core of the core-shell structure is at least one or a combination selected from the group consisting of: silicon (Si), germanium (Ge), selenium (Se), zinc (Zn), tellurium (Te), boron (B), nitrogen (N), phosphorus (P), arsenic (As), zinc sulfide (ZnS), zinc selenide (ZnSe), zinc telluride (ZnTe), mercury sulfide (HgS), mercury selenide (HgSe), mercury telluride (HgTe), aluminum nitride (AlN), aluminum phosphide (AlP), aluminum arsenide (AlAs), aluminum antimonide (AlSb), gallium nitride (GaN), gallium phosphide (GaP), gallium arsenide (GaAs), gallium antimonide (GaSb), gallium selenide (GaSe), indium nitride (InN), indium phosphide (InP), indium arsenide (InAs), indium antimonide (InSb), thallium nitride (TlN), thallium phosphide (TlP), thallium arsenide (TlAs), thallium antimonide (TlSb), lead sulfide (PbS), lead selenide (PbSe), and lead telluride (PbTe). Preferably, the core of the core-shell structure is indium phosphide (InP), and in the core-shell structure of the quantum dots, the element content of indium phosphide (InP) in the core layer gradually decreases from the core to the shell. Through this configuration, the quantum dots of the present disclosure can have a photoluminescence quantum yield that is greater than or equal to 90%, and a long-term stability can also be effectively achieved.

The shell of the core-shell structure can be single-layered or multi-layered, and its material is at least one or a combination selected from the group consisting of: zinc oxide (ZnO), zinc sulfide (ZnS), zinc selenide (ZnSe), zinc telluride (ZnTe), magnesium oxide (MgO), magnesium sulfide (MgS), magnesium selenide (MgSe), magnesium telluride (MgTe), mercury oxide (HgO), mercury sulfide (HgS), mercury selenide (HgSe), mercury telluride (HgTe), aluminum nitride (AlN), aluminum phosphide (AlP), aluminum arsenide (AlAs), aluminum antimonide (AlSb), gallium nitride (GaN), gallium phosphide (GaP), gallium arsenide (GaAs), gallium antimonide (GaSb), indium nitride (InN), indium phosphide (InP), indium arsenide (InAs), indium antimonide (InSb), thallium nitride (TlN), thallium phosphide (TlP), thallium arsenide (TlAs), thallium antimonide (TlSb), lead sulfide (PbS), lead selenide (PbSe), lead telluride (PbTe), indium gallium phosphide (InₓGa₁₋ₓP), copper indium sulfide (CuInS₂), copper indium selenide (CuInSe₂), copper indium sulfide selenide (CuInSₓSe₂₋ₓ), copper indium gallium sulfide (CuInₓGa₁₋ₓS₂), copper indium gallium selenide (CuInₓGa₁₋ₓSe₂), copper gallium sulfide (CuGaS₂), copper indium aluminum selenide (CuInₓAl₁₋ₓ—Se₂), copper gallium aluminum selenide (CuGaₓAl₁₋ₓSe₂), copper indium sulfide zinc sulfide (CuInS₂ₓZnS₁₋ₓ), and copper indium selenide zinc selenide (CuInSe₂ₓZnSe₁₋ₓ).

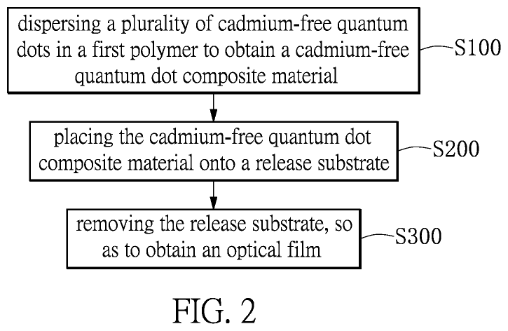

Referring to FIG. 2, the present disclosure also provides a method for manufacturing the optical film. The method includes: dispersing the plurality of cadmium-free quantum dots in the first polymer to obtain a cadmium-free quantum dot composite material (step S100); placing the cadmium-free quantum dot composite material onto a release substrate, and curing the cadmium-free quantum dot composite material (step S200); and removing the release substrate, so as to obtain the optical film (step S300).

The composition of the first polymer and the cadmium-free quantum dots are as illustrated above. Preferably, in the step S100, the plurality of quantum dots are dispersed in the monofunctional acrylic monomer. Then, the inhibitor is added, which is followed by the thiol compound. The bifunctional acrylic monomer and the multifunctional acrylic monomer are also added and mixed. Finally, the photoinitiator, the scattering particles, and the organosilicon grafted oligomer are added.

That is to say, in the step of dispersing the plurality of cadmium-free quantum dots in the first polymer, the cadmium-free quantum dots are not dispersed in a completely mixed first polymer. Instead, these cadmium-free quantum dots are pre-dispersed in a specific composition, and then other components are further added for a thorough mixing.

In the step S200, the cadmium-free quantum dot composite material is placed onto the release substrate, and is further attached with another release substrate, such that the cadmium-free quantum dot composite material is molded and interposed between the two release substrates. Then, the cadmium-free quantum dot composite material is subjected to a curing treatment with use of an ultraviolet (UV) light.

Apart from the foregoing steps, the method for manufacturing the optical film of the present disclosure further includes: performing a cutting process to cut the optical film into at least one required size; and performing a winding process to wind the rest of the optical film into a roll for use or storage. However, the aforementioned example describes only one of the embodiments of the present disclosure, and the present disclosure is not intended to be limited thereto.

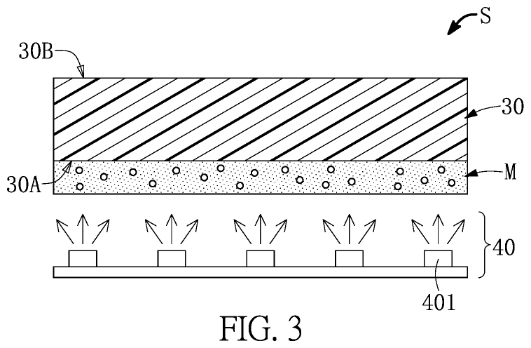

Referring to FIG. 3, the present disclosure further provides a backlight module S, which includes: a light guide unit 30, at least one light emitting unit 40, and the optical film M. The light guide unit 30 has a light input side 30A. The at least one light emitting unit 40 is positioned relative to the light input side 30A, and includes a plurality of light emitting elements 401. The optical film M is positioned relative to the light input side 30A, and is disposed between the light guide unit 30 and the at least one light emitting unit 40. Specifically, the light guide unit 30 has the light input side 30A and a light output side 30B that are opposite to each other, and the optical film M is disposed on the light input side 30A. More specifically, the optical film M is the above-mentioned optical film of the present disclosure. However, the aforementioned example describes only one of the embodiments of the present disclosure, and the present disclosure is not intended to be limited thereto.

### EXAMPLES

Cadmium-free quantum dot gel layers of Examples 1 to 3 and Comparative Examples 1 to 5 are prepared according to formulas and ratios as shown in Table 1, and further undergo product quality tests. Specifically, the following ratios are based on the total weight of the cadmium-free quantum dot gel layer being 100 wt %.

After the above-mentioned cadmium-free quantum dot composite material is placed onto the release substrate and is attached with another release substrate, the curing treatment is conducted with UV radiation. Finally, the release substrate is removed, so as to obtain the cadmium-free quantum dot gel layer of the present disclosure.

TABLE 1

| | Examples | | | Comparative Examples | | | | |
|---|---|---|---|---|---|---|---|---|
| Ratio (wt %) | 1 | 2 | 3 | 1 | 2 | 3 | 4 | 5 |
| Cadmium-free | 1% | 1% | 1% | 1% | 1% | 1% | 1% | 1% |
| quantum dots | | | | | | | | |
| Photoinitiator | 3% | 3% | 3% | 3% | 3% | 3% | 3% | 3% |
| Scattering | 15% | 15% | 15% | 15% | 15% | 15% | 15% | 15% |
| particles | | | | | | | | |
| Primary | 10.9% | 8% | 8% | 0% | 25% | 15.9% | 4% | 16.9% |
| mercaptan | | | | | | | | |
| Secondary | 10% | 7.9% | 12.9% | 0% | 20% | 0% | 16.9% | 4% |
| mercaptan | | | | | | | | |
| Monofunctional | 15% | 10% | 10% | 29.9% | 10.9% | 15% | 15% | 15% |
| acrylic | | | | | | | | |
| monomer | | | | | | | | |
| Bifunctional | 10% | 5% | 10% | 11% | 5% | 10% | 10% | 10% |
| acrylic | | | | | | | | |
| monomer | | | | | | | | |
| Multifunctional | 25% | 40% | 20% | 30% | 10% | 30% | 25% | 25% |
| acrylic | | | | | | | | |
| monomer | | | | | | | | |
| Organosilicon | 10% | 10% | 20% | 10% | 10% | 10% | 10% | 10% |
| grafted | | | | | | | | |
| oligomer | | | | | | | | |
| Inhibitor | 0.1% | 0.1% | 0.1% | 0.1% | 0.1% | 0.1% | 0.1% | 0.1% |
| Thickness | 200 | 200 | 200 | 200 | 200 | 200 | 200 | 200 |
| (μm) | | | | | | | | |
| Water-oxygen | 450 | 350 | 400 | 150 | 200 | 250 | 290 | 295 |
| resistant | | | | | | | | |
| reliability | | | | | | | | |
| (hour) | | | | | | | | |
| Transmittance | 75% | 75% | 75% | 75% | 75% | 75% | 75% | 75% |
| Refractive | 1.57 | 1.55 | 1.54 | 1.49 | 1.47 | 1.57 | 1.57 | 1.57 |
| index | | | | | | | | |
| Adhesion | not | not | not | not | separate | not | not | not |
| | separate | separate | separate | separate | | separate | separate | separate |
| Shrinkage | no | no | no | warpage | no | no | no | no |
| | warpage | warpage | warpage | | warpage | warpage | warpage | warpage |
| Luminance | 4500 | 4350 | 4300 | 3550 | 4500 | 4450 | 4000 | 3950 |
| (Cd/m²) | | | | | | | | |

In Table 1, the test of water-oxygen resistant reliability is conducted by placing a backlight module in an environment where a temperature is 65° C. and a relative humidity is 95%. The backlight module is continuously irradiated by a blue backlight, and the time taken for a chromaticity coordinate deviation to reach 0.01 is recorded.

Adhesion: using a tensile testing machine to test an adhesion degree of the optical film.

Shrinkage: placing the optical film in an oven at 85° C. for half an hour, so as to observe its state of shrinkage. The optical film is indicated to have “warpage” when its degree of warpage is greater than or equal to 0.2 cm, and is indicated to have “no warpage” when its degree of warpage is less than 0.2 cm.

Luminance: using a spectrophotometer (model: SR-3AR) to measure a luminance of a mixed light beam generated by the backlight module with use of a blue light source (power: 12 W; chromaticity coordinate: x=0.155, y=0.026; wavelength: 450 nm; FWHM: 20 nm).

According to the results of Table 1, the first polymer of the present disclosure includes the primary mercaptan and the second mercaptan at the same time, which allows the cadmium-free quantum dot gel layer to have good water-oxygen barrier effects. In the test of water-oxygen resistant reliability, the duration for each of Examples 1 to 3 is greater than 300 hours.

### Beneficial Effects of the Embodiments

In conclusion, in the optical film, the method for manufacturing the same, and the backlight module provided by the present disclosure, by virtue of the thiol compound including the primary mercaptan and the secondary mercaptan and the weight ratio of the primary mercaptan to the secondary mercaptan ranging from 1:3 to 3:1, water-oxygen resistant properties of the cadmium-free quantum dot gel layer can be enhanced. In addition, the shielding layer does not need to be attached to one side or both sides of the cadmium-free quantum dot gel layer, such that a film layer thickness can be effectively reduced. Accordingly, this optical film can be applied to optical products that are light and thin in size.

The conventional optical film made from the cadmium-free quantum dots is still limited to having poor water-oxygen resistant effects. If the shielding layer is omitted, such an optical film will have decreased water and oxygen tolerance, and its mechanical strength will also be insufficient. The organosilicon grafted oligomer of the present disclosure can not only increase the weather resistance of the polymer, but can also enhance the mechanical strength of the polymer.

More specifically, the thiol compound provides the non-aromatic compound containing the sulfhydryl (—SH) functional group, which can form a better bond with the quantum dots. Accordingly, the dispersity of the quantum dots can be improved. The content of the thiol compound of the present disclosure is higher in comparison to that of the related art, which results in a higher degree of polymerization.

During preparation and mixing of the formulas of the present disclosure, an issue of mutual influence is also taken into particular consideration. As such, after numerous experiments, a specific inhibitor is further selected in the present disclosure, so as to effectively slow down the reaction rate and prevent the thiol compound and the multifunctional acrylic monomer from self-reacting at the room temperature. In this way, an improved processability can be provided, and a more stable preservation can be obtained.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An optical film, characterized in that the optical film is formed by a cadmium-free quantum dot gel layer, and the cadmium-free quantum dot gel layer includes a first polymer and a plurality of cadmium-free quantum dots dispersed in the first polymer; wherein, based on a total weight of the cadmium-free quantum dot gel layer being 100 wt %, a content of the cadmium-free quantum dots ranges from 0.1 wt % to 5 wt %, and the first polymer includes:
1 wt % to 5 wt % of a photoinitiator;
3 wt % to 30 wt % of scattering particles;
10 wt % to 40 wt % of a thiol compound;
5 wt % to 30 wt % of a monofunctional acrylic monomer;
5 wt % to 20 wt % of a bifunctional acrylic monomer;
10 wt % to 40 wt % of a multifunctional acrylic monomer;
5 wt % to 20 wt % of an organosilicon grafted oligomer; and
100 ppm to 2,000 ppm of an inhibitor;
wherein the thiol compound includes a primary mercaptan and a secondary mercaptan, and a weight ratio of the primary mercaptan to the secondary mercaptan ranges from 1:3 to 3:1.

2. The optical film according to claim 1, wherein the primary mercaptan is selected from the group consisting of: 2, 2′-(ethylenedioxy)diethyl mercaptan, 2, 2′-thiodiethyl mercaptan, trimethylolpropane tris(3-mercaptopropionate), polyethylene glycol dithiol, pentaerythritol tetrakis(3-mercaptopropionate), and ethylene glycol dimercaptoacetate; wherein the secondary mercaptan is selected from the group consisting of: ethyl 2-mercaptopropionate, pentaerythritol tetrakis(3-mercaptobutyrate), 1, 3, 5-tris(3-mercapto butyloxyethyl)-1, 3, 5-triazine-2, 4, 6(1H, 3H, 5H)-trione, and 1,4-butanediol bis(3-mercaptobutyric acid) ester.

3. The optical film according to claim 1, wherein the monofunctional acrylic monomer is selected from the group consisting of: dicyclopentadiene methacrylate, triethylene glycol ethyl ether methacrylate, alkoxylated lauryl acrylate, isobornyl methacrylate, lauryl methacrylate, stearyl methacrylate, lauryl acrylate, isobornyl acrylate, tridecyl acrylate, caprolactone acrylate, octylphenol acrylate, and alkoxylated acrylate.

4. The optical film according to claim 1, wherein the bifunctional acrylic monomer is selected from the group consisting of: bisphenol A ethoxylate dimethacrylate, 1,3-butanediol diacrylate, 1,4-butanediol dimethacrylate, 1,6-hexanediol diacrylate, tetra(ethylene glycol) diacrylate, and polyethylene glycol diacrylate.

5. The optical film according to claim 1, wherein the multifunctional acrylic monomer is selected from the group consisting of: trimethylolpropane triacrylate, ethoxylated trimethylolpropane triacrylate, ditrimethylolpropane tetraacrylate, pentaerythritol tetraacrylate, dipentaerythritol pentaacrylate, and ethoxylated pentaerythritol tetraacrylate.

6. The optical film according to claim 1, wherein the organosilicon grafted oligomer is a polyoctahedral silsesquioxane.

7. The optical film according to claim 1, wherein the cadmium-free quantum dots are quantum dots that have a core-shell structure; wherein a core of the core-shell structure is at least one selected from the group consisting of: silicon (Si), germanium (Ge), selenium (Se), zinc (Zn), tellurium (Te), boron (B), nitrogen (N), phosphorus (P), arsenic (As), zinc sulfide (ZnS), zinc selenide (ZnSe), zinc telluride (ZnTe), mercury sulfide (HgS), mercury selenide (HgSe), mercury telluride (HgTe), aluminum nitride (AlN), aluminum phosphide (AlP), aluminum arsenide (AlAs), aluminum antimonide (AlSb), gallium nitride (GaN), gallium phosphide (GaP), gallium arsenide (GaAs), gallium antimonide (GaSb), gallium selenide (GaSe), indium nitride (InN), indium phosphide (InP), indium arsenide (InAs), indium antimonide (InSb), thallium nitride (TlN), thallium phosphide (TlP), thallium arsenide (TlAs), thallium antimonide (TlSb), lead sulfide (PbS), lead selenide (PbSe), and lead telluride (PbTe).

8. The optical film according to claim 7, wherein a shell of the core-shell structure is at least one selected from the group consisting of: zinc oxide (ZnO), zinc sulfide (ZnS), zinc selenide (ZnSe), zinc telluride (ZnTe), magnesium oxide (MgO), magnesium sulfide (MgS), magnesium selenide (MgSe), magnesium telluride (MgTe), mercury oxide (HgO), mercury sulfide (HgS), mercury selenide (HgSe), mercury telluride (HgTe), aluminum nitride (AlN), aluminum phosphide (AlP), aluminum arsenide (AlAs), aluminum antimonide (AlSb), gallium nitride (GaN), gallium phosphide (GaP), gallium arsenide (GaAs), gallium antimonide (GaSb), indium nitride (InN), indium phosphide (InP), indium arsenide (InAs), indium antimonide (InSb), thallium nitride (TlN), thallium phosphide (TlP), thallium arsenide (TlAs), thallium antimonide (TlSb), lead sulfide (PbS), lead selenide (PbSe), lead telluride (PbTe), indium gallium phosphide (InₓGa₁₋ₓP), copper indium sulfide (CuInS₂), copper indium selenide (CuInSe₂), copper indium sulfide selenide (CuInSₓSe₂₋ₓ), copper indium gallium sulfide (CuInₓGa₁₋ₓS₂), copper indium gallium selenide (CuInₓGa₁₋ₓSe₂), copper gallium sulfide (CuGaS₂), copper indium aluminum selenide (CuInₓAl₁₋ₓSe₂), copper gallium aluminum selenide (CuGaₓAl₁₋ₓSe₂), copper indium sulfide zinc sulfide (CuInS₂ₓZnS₁₋ₓ), and copper indium selenide zinc selenide (CuInSe₂ₓZnSe₁₋ₓ).

9. A method for manufacturing an optical film, comprising:
(a) dispersing a plurality of cadmium-free quantum dots in a first polymer to obtain a cadmium-free quantum dot composite material; wherein, based on a total weight of the cadmium-free quantum dot composite material being 100 wt %, a content of the cadmium-free quantum dots ranges from 0.1 wt % to 5 wt %, and the first polymer includes:
1 wt % to 5 wt % of a photoinitiator;
3 wt % to 30 wt % of scattering particles;
10 wt % to 40 wt % of a thiol compound;
5 wt % to 30 wt % of a monofunctional acrylic monomer;
5 wt % to 20 wt % of a bifunctional acrylic monomer;
10 wt % to 40 wt % of a multifunctional acrylic monomer;
5 wt % to 20 wt % of an organosilicon grafted oligomer; and
100 ppm to 2,000 ppm of an inhibitor;
wherein the thiol compound includes a primary mercaptan and a secondary mercaptan, and a weight ratio of the primary mercaptan to the secondary mercaptan ranges from 1:3 to 3:1;
(b) placing the cadmium-free quantum dot composite material onto a release substrate, and curing the cadmium-free quantum dot composite material; and
(c) removing the release substrate, so as to obtain the optical film.

10. A backlight module, comprising:
a light guide unit having a light input side;
at least one light emitting unit corresponding in position to the light input side; and
an optical film corresponding in position to the light input side and being disposed between the light guide unit and the at least one light emitting unit, wherein the optical film is formed by a cadmium-free quantum dot gel layer, and the cadmium-free quantum dot gel layer includes a first polymer and a plurality of cadmium-free quantum dots dispersed in the first polymer;
wherein, based on a total weight of the cadmium-free quantum dot gel layer being 100 wt %, a content of the cadmium-free quantum dots ranges from 0.1 wt % to 5 wt %, and the first polymer includes:
1 wt % to 5 wt % of a photoinitiator;
3 wt % to 30 wt % of scattering particles;
10 wt % to 40 wt % of a thiol compound;
5 wt % to 30 wt % of a monofunctional acrylic monomer;
5 wt % to 20 wt % of a bifunctional acrylic monomer;
10 wt % to 40 wt % of a multifunctional acrylic monomer;
5 wt % to 20 wt % of an organosilicon grafted oligomer; and
100 ppm to 2,000 ppm of an inhibitor;
wherein the thiol compound includes a primary mercaptan and a secondary mercaptan, and a weight ratio of the primary mercaptan to the secondary mercaptan ranges from 1:3 to 3:1.
